(19) United States
(12) Patent Application Publication
(10) Pub. No.: US 2025/0311216 A1
(43) Pub. Date: Oct. 2, 2025

(54) MEMORY DEVICE AND METHOD OF MANUFACTURING THE MEMORY DEVICE

(71) Applicant: SK hynix Inc., Icheon-si Gyeonggi-do (KR)

(72) Inventor: Dae Sung EOM, Icheon-si Gyeonggi-do (KR)

(73) Assignee: SK hynix Inc., Icheon-si Gyeonggi-do (KR)

(21) Appl. No.: 18/898,116

(22) Filed: Sep. 26, 2024

(30) Foreign Application Priority Data
Apr. 2, 2024 (KR) 10-2024-0044574

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A memory device and a manufacturing method are provided. The memory device includes a first gate conductive pattern disposed within a cell region and a word line contact region and extending in a first direction; and a second gate conductive pattern sequentially disposed with the first gate conductive pattern and extending in the first direction. Each of the first gate conductive pattern and the second gate conductive pattern includes a first extension extending in parallel with a second extension within the word line contact region; a first extending member extending in a third direction from an end of the first extension and a second extending member extending in the third direction from an end of the second extension, wherein the third direction is orthogonal to the first direction; and a connection connecting the first extending member to the second extending member.

### CROSS-REFERENCE TO RELATED APPLICATION

The present application claims priority under 35 U.S.C. § 119 (a) to Korean patent application number 10-2024-0044574 filed on Apr. 2, 2024, in the Korean Intellectual Property Office, the entire application of which is incorporated herein by reference.

### BACKGROUND

### 1. Technical Field

The present disclosure generally relates to a memory device and a manufacturing method thereof, including but not limited to a three-dimensional memory device and a manufacturing method thereof.

### 2. Related Art

A memory device includes a memory cell array and a peripheral circuit connected to the memory cell array. The memory cell array includes a plurality memory cells capable of storing data, and the peripheral circuit is configured to perform a general operation including a program operation, a read operation, an erase operation, and the like.

In order to improve the degree of integration of the memory device, the memory cell array includes three-dimensionally arranged memory cells on the peripheral circuit.

### SUMMARY

In accordance with an embodiment of the present disclosure, a memory device includes: a first gate conductive pattern disposed within a cell region and a word line contact region and extending in a first direction; and a second gate conductive pattern sequentially disposed with the first gate conductive pattern and extending in the first direction, wherein each of the first gate conductive pattern and the second gate conductive pattern includes: a first extension extending in parallel with a second extension within the word line contact region; a first extending member extending in a third direction from an end of the first extension and a second extending member extending in the third direction from an end of the second extension, wherein the third direction is orthogonal to the first direction; and a connection connecting the first extending member to the second extending member.

In accordance with an embodiment of the present disclosure, a memory device includes: a first gate conductive pattern disposed within a first cell region, a word line contact region, and a second cell region, which first cell region, word line contact region, and second cell region are sequentially disposed and extend in a first direction; and a second gate conductive pattern sequentially disposed with the first gate conductive pattern and extending in the first direction, wherein each of the first gate conductive pattern and the second gate conductive pattern includes: a first extension extending in parallel with a second extension in the first direction within the word line contact region; a first extending member extending in a third direction from an end of the first extension and a second extending member extending in the third direction from an end of the second extension, wherein the third direction is orthogonal to the first direction; and a connection connecting the first extending member to the second extending member, and wherein the first gate conductive pattern and the second gate conductive pattern have a concave pattern shape within the word line contact region.

In accordance with an embodiment of the present disclosure, a method of manufacturing a memory device includes: forming an insulating structure, including word line contact pads, on a substrate including a first cell region, a word line contact region, and a second cell region; forming a doped semiconductor layer on the insulating structure and etching the doped semiconductor layer formed within the word line contact region to form a trench between a first sidewall and a second sidewall of the doped semiconductor layer; forming a stack structure in which interlayer insulating layers are alternately stacked with sacrificial layers on the doped semiconductor layer, the first sidewall, the second sidewall, and a surface of the insulating structure adjacent to the trench; forming in the stack structure a first opening near the first sidewall through which a surface of the doped semiconductor layer is exposed and a second opening near the first sidewall through which a surface of the insulating structure adjacent to the trench is exposed by etching the stack structure within the word line contact region; forming sacrificial patterns extending in a third direction parallel to the first sidewall by partially etching the sacrificial layers exposed through the first opening and the second opening; and forming insulating patterns by filling, with an insulating material, the first opening, the second opening, and spaces where the sacrificial layers are removed by the etching.

### BRIEF DESCRIPTION OF THE DRAWINGS

FIG. 1 is a block diagram illustrating a memory device in accordance with an embodiment of the present disclosure.

FIG. 2A and FIG. 2B are perspective views illustrating structures of a peripheral circuit structure and a cell stack structure in accordance with an embodiment of the present disclosure.

FIG. 3 is a circuit diagram illustrating a memory cell array and a row decoder in accordance with an embodiment of the present disclosure.

FIG. 4 is a perspective view illustrating a connection structure including gate conductive patterns and word line contacts in accordance with an embodiment of the present disclosure.

FIG. 5A, FIG. 5B, FIG. 6, FIG. 7A, FIG. 7B, FIG. 8A, FIG. 8B, FIG. 8C, FIG. 9A, FIG. 9B, FIG. 10, FIG. 11A, and FIG. 11B are views of a memory device formed utilizing a method of manufacturing the memory device in accordance with an embodiment of the present disclosure.

FIG. 12 is a block diagram illustrating a configuration of a memory system in accordance with an embodiment of the present disclosure.

FIG. 13 is a block diagram illustrating a configuration of a computing system in accordance with an embodiment of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “vertical,” “horizontal,” “top,” “bottom,” “above,” “under,” “over,” “on,” “side,” “upper,” “uppermost,” “lower,” “lowermost,” “column,” “row,” “downwardly,” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas.

In the drawing figures, dimensions may be precise for clarity of illustration. When one element is identified as “connected” to another element, the elements may be connected directly or through at least one intervening element between the elements. When two elements are identified as “directly connected” one element is directly connected to the other element without an intervening element between the two elements. When one element is identified as “on,” “over,” “under,” or “between” another element, the elements may directly contact each other or an intervening element may be disposed between the elements.

A memory device and a manufacturing method are described in which word line contacts connected to word lines corresponding to different memory blocks are formed in a region between the memory blocks.

Embodiments of the present disclosure are described in detail with reference to the accompanying drawings such that a person skilled in the art may readily implement the concepts of the present disclosure.

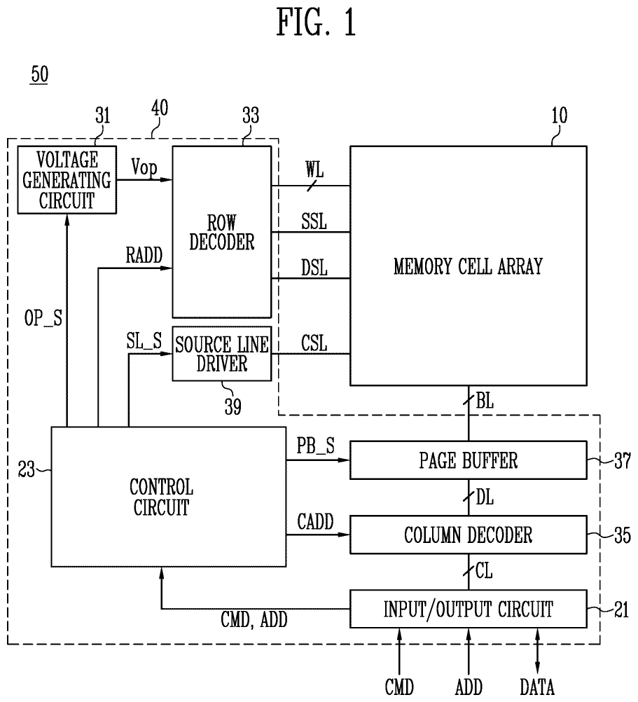

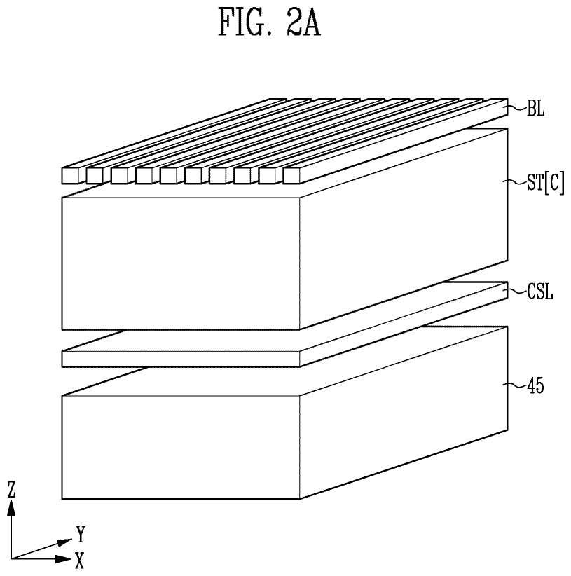

FIG. 1 is a block diagram illustrating a memory device in accordance with an embodiment of the present disclosure.

Referring to FIG. 1, the semiconductor memory device 50 includes a peripheral circuit 40 and a memory cell array 10.

The peripheral circuit 40 is configured to perform a general operation including a program operation that stores data in the memory cell array 10, a read operation that outputs data stored in the memory cell array 10, and an erase operation that erases data stored in the memory cell array 10. In an embodiment, the peripheral circuit 40 includes an input/output circuit 21, a control circuit 23, a voltage generating circuit 31, a row decoder 33, a column decoder 35, a page buffer 37, and a source line driver 39.

The memory cell array 10 includes a plurality of memory cells in which data is stored. The memory cells may be three-dimensionally arranged. The memory cell array 10 includes one or more cell strings. Each of the cell strings includes at least one drain select transistor DST, a plurality of memory cells, and at least one source select transistor SST, which are connected between any one of bit lines BL and a common source line CSL. The at least one drain select transistor DST is connected to a drain select line DSL, the plurality of memory cells is connected to a plurality of word lines, and the at least one source select transistor SST is connected to a source select line SSL.

The input/output circuit 21 transfers, to the control circuit 23, a command CMD and an address ADD received from an external device, for example, a memory controller, external to the memory device 50. The input/output circuit 21 transmits data DATA received from the external device to a column decoder 35 or outputs data DATA received from the column decoder 35 to the external device.

The control circuit 23 controls the voltage generating circuit 31, the row decoder 32, the column decoder 35, the page buffer 37, and the source line driver 39 to perform a program operation, a read operation, and an erase operation in response to the command CMD and the address ADD, which are received through the input/output circuit 21. For example, the control circuit 23 generates and outputs an operation signal OP_S, a row address RADD, a source line control signal SL_S, a page buffer control signal PB_S, and a column address CADD in response to the command CMD and the address ADD.

The voltage generating circuit 31 generates various operating voltages Vop used for a program operation, a read operation, and an erase operation in response to receiving the operation signal OP_S.

The row decoder 33 selectively transfers the operating voltages Vop generated by the voltage generating circuit 31 to the drain select line DSL, the word lines WL, and the source select line SSL in response to the row address RADD. The row decoder 33 selectively discharges voltages at the drain select line DSL, the word lines WL, and the source select line SSL.

The column decoder 35 transmits data DATA received from the input/output circuit 21 to the page buffer 37 or transmit data DATA stored in the page buffer 37 to the input/output circuit 21 in response to the column address CADD. For example, during a program operation, the column decoder 35 transmits data DATA received through column lines CL from the input/output circuit 21 to the page buffer 37 in response to the column address CADD. During a read operation, the column decoder 35 receives data DATA stored in the page buffer 37 through data lines DL and transmits the received data DATA to the input/output circuit 21.

During a program operation, the page buffer 37 temporarily stores data DATA received from the column decoder 35 and controls a voltage of the bit lines BL, based on the temporarily stored data DATA. During a read operation, the page buffer 37 senses a voltage or a current of the bit lines BL and latches data DATA according to a result of the sensing. The page buffer 37 is operated in response to the page buffer control signal PB_S.

The source line driver 39 controls a voltage applied to the common source line CSL in response to the source line control signal SL_S. For example, during an erase operation, the source line driver 39 applies an erase voltage to the common source line CSL.

In order to improve the degree of integration of the memory device, a cell stack structure of the memory cell array 10 is disposed over or overlaps with the peripheral circuit 40. For example, after a peripheral circuit structure is formed on a substrate, the cell stack structure is formed on or over the peripheral circuit structure 45 in the third direction Z.

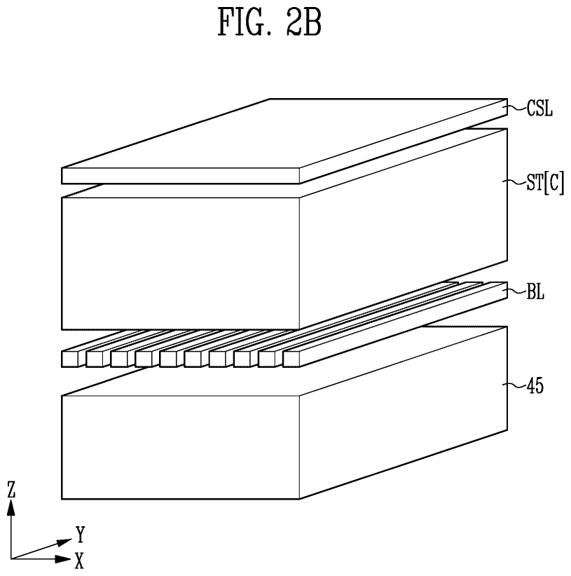

FIG. 2A and FIG. 2B are perspective views illustrating structures of a peripheral circuit structure and a cell stack structure in accordance with an embodiment of the present disclosure.

Referring to FIG. 2A and FIG. 2B, a common source line CSL and a plurality of bit lines BL are aligned in the third direction Z over or on the peripheral circuit structure 45. A cell stack structure ST[C] is disposed between the common source line CSL and the plurality of bit lines BL. The plurality of bit lines BL are arranged in a first direction X, which may be a horizontal direction, and each of the plurality of bit lines BL extends in a second direction Y orthogonal to the first direction X, which may be horizontal direction.

Referring to FIG. 2A, in an embodiment, the common source line CSL is disposed between the cell stack structure ST [C] and the peripheral circuit structure 45, and the bit lines BL are aligned with the common source line CSL in the third direction Z with the cell stack structure ST[C] interposed between the bit lines BL and the common source line CSL. The peripheral circuit structure 45, the common source line CSL, the cell stack structure ST[C], and the bit lines BL are sequentially stacked in the third direction Z, which may be the vertical direction.

Referring to FIG. 2B, in an embodiment, the bit lines BL are disposed between the cell stack structure ST[C] and the peripheral circuit structure 45, and the common source line CSL is aligned with the bit lines BL in the third direction Z with the cell stack structure ST[C] interposed between the common source line CSL and the bit lines BL.

In the present disclosure, the drawings illustrate the entirety of the cell stack structure ST[C] is aligned in the third direction Z with the peripheral circuit structure 45. For example, the cell stack structure ST[C] and the peripheral circuit structure 45 extend with the same dimensions in the first direction X and the second direction Y and neither the cell stack structure ST[C] nor the peripheral circuit structure 45 extends beyond the other in either the first direction X or the second direction Y. In other embodiments, the cell stack structure ST[C] partially overlaps with the peripheral circuit structure 45 in the first direction X and/or the second direction Y. For example, a region of the cell stack structure ST[C] may extend beyond the peripheral circuit structure 45 in the first direction X and/or the second direction Y, or a region of the peripheral circuit structure 45 may extend beyond the cell stack structure ST[C] in the first direction X and/or the second direction Y. The cell stack structure ST[C] and the peripheral circuit structure 45 may have different dimensions in the first direction X and/or the second direction Y.

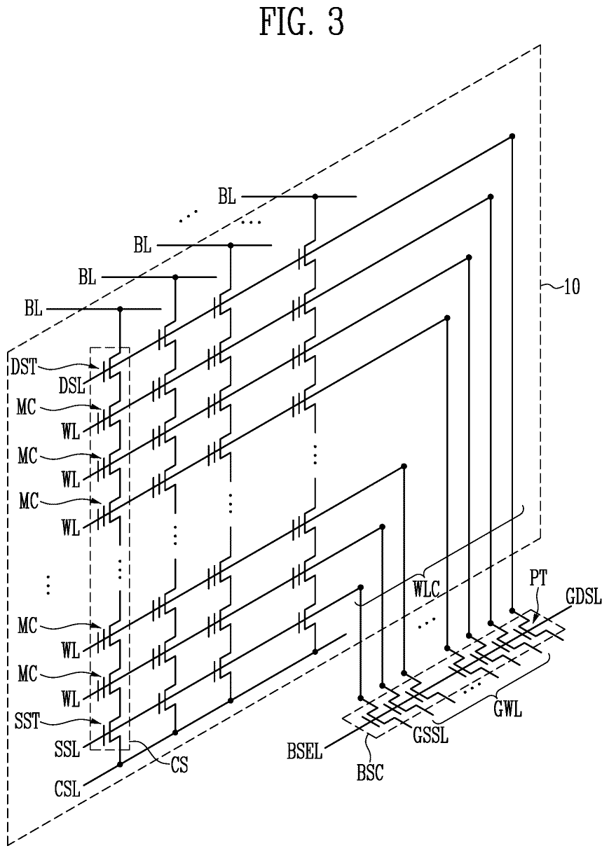

FIG. 3 is a circuit diagram illustrating a memory cell array and a row decoder in accordance with an embodiment of the present disclosure.

Referring to FIG. 3, the memory cell array 10 includes a plurality of cell strings CS respectively connected to a plurality of bit lines BL. The plurality of cell strings are commonly connected to the common source line CSL.

Each of the cell strings CS includes at least one source select transistor SST, a plurality of memory cells MC, and at least one drain select transistor DST, which are disposed between the common source line CSL and a bit line BL.

The source select transistors SST control electrical connection between the cell string CS and the common source line CSL. The drain select transistors DST control electrical connection between the cell string CS and the bit line BL.

One source select transistor SST is disposed between the common source line CSL and the plurality of memory cells MC. Alternatively, two or more source select transistors connected in series may be disposed between the common source line CSL and the plurality of memory cells MC. One drain select transistor DST is disposed between the bit line BL and the plurality of memory cells MC. Alternatively, two or more drain select transistors connected in series may be disposed between the bit line BL and the plurality of memory cells MC.

The plurality of memory cells MC are respectively connected to word lines WL. Operations of the plurality of memory cells are controlled by cell gate signals applied to the word lines WL. The source select transistor SST is connected to a source select line SSL. Operation of the source select transistor SST is controlled by a source gate signal applied to the source select line SSL. The drain select transistor DST is connected to a drain select line DSL. Operation of the drain select transistor DST is controlled by a drain gate signal applied to the drain select line DSL.

The source select line SSL, the drain select line DSL, and the word lines WL are connected to a block select circuit BSC. The block select circuit BSC is included in the row decoder 33 described with reference to FIG. 1. In an embodiment, the block select circuit BSC includes pass transistors PT, each connected to one of the source select line SSL, the drain select line DSL, and the word lines WL. Gates of the pass transistors PT are connected to a block select line BSEL. The pass transistors PT transfer operating voltages applied to global lines GSSL, GWL, and GDSL to the source select line SSL, the drain select line DSL, and the word lines WL in response to a block select signal applied to the block select line BSEL.

The block select circuit BSC is connected to the source select line SSL, the drain select line DSL, and the word lines WL via word line contacts WLC.

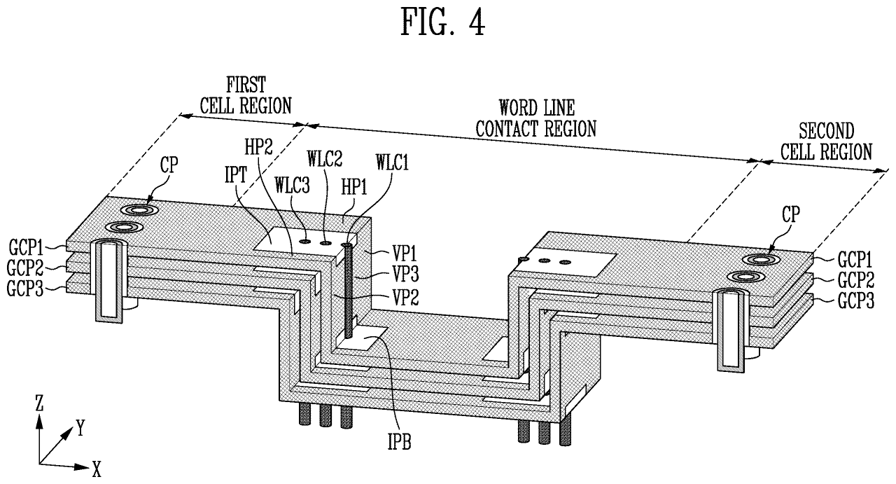

FIG. 4 is a perspective view illustrating a connection structure including gate conductive patterns and word line contacts in a first cell region, a word line contact region, and a second cell region in accordance with an embodiment of the present disclosure.

Referring to FIG. 4, a plurality of gate conductive patterns GCP1, GCP2, and GCP3 are formed within a first cell region, a word line contact region, and a second cell region of the connection structure. The first cell region, the word line contact region, and the second cell region are arranged side-by-side in the first direction X. The word line contact region is disposed between the first cell region and the second cell region. Although three gate conductive patterns are illustrated, more than three gate conductive patterns may be included.

The plurality of gate conductive patterns GCP1, GCP2, and GCP3 correspond to the drain select line DSL, the word lines WL, and the source select line SSL, which are shown in FIG. 3. The first cell region and the second cell region may be regions of a single plane included in the memory cell array 10 shown in FIG. 1. For example, a first memory block is disposed in the first cell region, and a second memory block is disposed in the second cell region.

The conductive patterns GCP1, GCP2, and GCP3 are stacked in the third direction Z, and an interlayer insulating layer is disposed between consecutive gate conductive patterns, such that the gate conductive patterns GCP1, GCP2, and GCP3 are physically and electrically isolated from each other.

The gate conductive patterns GCP1, GCP2, and GCP3 formed within the first cell region extend in the first direction X, and a plurality of cell plugs CP extend through the gate conductive patterns GCP1, GCP2, and GCP3 in the third direction Z. Sidewalls of the plurality of cell plugs CP are surrounded by the gate conductive patterns GCP1, GCP2, and GCP3.

Each of the conductive patterns GCP1, GCP2, and GCP3 is disposed within the first cell region and the second cell region and extends in the first direction X and is formed along a surface of a concave portion on the word line contact region. Accordingly, each of the gate conductive patterns GCP1, GCP2, and GCP3 may include a concave pattern shape within the word line contact region.

Each of the gate conductive patterns GCP1, GCP2, and GCP3 includes first extension HP1 and second extension HP2 extending in the first direction X and formed within the word line contact region. An upper insulating pattern IPT is disposed between the first extension HP1 and the second extension HP2. The first extension HP1 and the second extension HP2 of each of the gate conductive patterns GCP1, GCP2, and GCP3 extend in different lengths. For example, extensions HP1 and HP2 of an uppermost gate conductive pattern extend longer than the extensions HP1 and HP2 of a lowermost gate conductive pattern. The extensions HP1 and HP2 of the first gate conductive pattern GCP1 are longer than the extensions HP1 and HP2 of the second gate conductive pattern GCP2, and the extensions HP1 and HP2 of the second gate conductive pattern GCP2 are longer than the extensions HP1 and HP2 of the third gate conductive pattern GCP3.

Each of the gate conductive patterns GCP1, GCP2, and GCP3 includes a first extending member VP1 and a second extending member VP2 extending in the third direction Z within the word line contact region. For example, the ends of the first extension HP1 and the end of the second extension HP2 of each of the gate conductive patterns GCP1, GCP2, and GCP3 is connected to the first extending member VP1 and the second extending member VP2, respectively. The end of the first extension HP1 is connected to the first extending member VP1, the end of the second extension HP2 is connected to the second extending member VP2, and the extending members VP1 and VP2 extend in the third direction Z or downwardly from the extensions HP1 and HP2 as shown in FIG. 4. The first extending member VP1 and the second extending member VP2 of each of the gate conductive patterns GCP1, GCP2, and GCP3 are sequentially arranged in the first direction X. The extensions HP1 and HP2 and the extending members VP1 and VP2 may be formed of the same materials, may be formed at the same time, and may be contiguously formed or formed as separate sections.

Each of the gate conductive patterns GCP1, GCP2, and GCP3 includes a connection VP3 that connects the first extending member VP1 to the second extending member VP2. The connection VP3 extends in the third direction Z in the example of FIG. 4. The upper insulating pattern IPT is disposed between a first end of the first extending member VP1 and a first end of the second extending member VP2. A lower insulating pattern IPB is disposed between a second end of the first extending member VP1 and a second end of the second extending member VP2. The connection VP3 is disposed between the upper insulating pattern IPT and the lower insulating pattern IPB. The first extending member VP1, the second extending member VP2, and the vertical connection portion VP3 of each of the gate conductive patterns GCP1, GCP2, and GCP3 have a H shape in the word line contact region. The first ends of the connections VP3 of the gate conductive patterns GCP1, GCP2, and GCP3 are each located at different heights or levels in the third direction Z. The second ends of the connections VP3 of the gate conductive patterns GCP1, GCP2, and GCP3 are each located at different heights or levels in the third direction Z.

The lower insulating pattern IPB of each of the first to third gate conductive patterns GCP1, GCP2, and GCP3 extends in the first direction X away from the second end of the first extending member VP1 and the second end of the second extending member VP2 of each of the gate conductive patterns GCP1, GCP2, and GCP3. The lower insulating pattern IPB of each of the gate conductive patterns GCP1, GCP2, and GCP3 extends with a different length in the first direction X. For example, the lower insulating pattern IPB of the gate conductive pattern GCP1 is shorter in length in the first direction X than the length of lower insulating pattern IPB of the gate conductive pattern GCP2, and the lower insulating pattern IPB of the gate conductive pattern GCP2 is shorter in length in the first direction X than the length of the lower insulating pattern IPB of the gate conductive pattern GCP3.

The connection VP3 of each of the gate conductive patterns GCP1, GCP2, and GCP3 is penetrated by word line contacts WLC1, WLC2, and WLC3, respectively. For example, a first word line contact WLC1 extends in the third direction Z through a connection VP3 of the first gate conductive pattern GCP1, and the first word line contact WLC1 is connected to or contacts the connection VP3 of the first gate conductive pattern GCP1. A second word line contact WLC2 extends in the third direction Z through a connection VP3 of the second gate conductive pattern GCP2, and the second word line contact WLC2 is connected to or contacts the connection VP3 of the second gate conductive pattern GCP2. A third word line contact WLC3 extends in the third direction Z through a connection VP3 of the third gate conductive pattern GCP3, and the third word line contact WLC3 is connected to or contacts the vertical connection portion VP3 of the third gate conductive pattern GCP3.

The extending members VP1 and VP2 of each of the gate conductive patterns GCP1, GCP2, and GCP3 may have the same length.

The first word line contact WLC1 extends through an upper insulating pattern IPT and a lower insulating pattern IPB of the first gate conductive pattern GCP1, a lower insulating pattern IPB of the second gate conductive pattern GCP2, and a lower insulating pattern IPB of the third gate conductive pattern GCP3. Accordingly, the first word line contact WLC1 is physically and electrically isolated from the second gate conductive pattern GCP2 and the third gate conductive pattern GCP3.

The second word line contact WLC2 extends through the upper insulating pattern IPT of the first gate conductive pattern GCP1, an upper insulating pattern IPT and the lower insulating pattern IPB of the second gate conductive pattern GCP2, and the lower insulating pattern IPB of the third gate conductive pattern GCP3. Accordingly, the second word line contact WLC2 is physically and electrically isolated from the first gate conductive pattern GCP1 and the third gate conductive pattern GCP3.

The third word line contact WLC3 extends through the upper insulating pattern IPT of the first gate conductive pattern GCP1, the upper insulating pattern IPT of the second gate conductive pattern GCP2, and an upper insulating pattern IPT and the lower insulating pattern IPB of the third gate conductive pattern GCP3. Accordingly, the third word line contact WLC3 is physically and electrically isolated from the first gate conductive pattern GCP1 and the second gate conductive pattern GCP2.

The word line contacts WLC1, WLC2, and WLC3 may be arranged in a straight line in the first direction X. In another embodiment, the word line contacts WLC1, WLC2, and WLC3 may be arranged in an oblique direction, for example, in both the first direction X and the second direction Y. In another embodiment, the word line contacts WLC1, WLC2, and WLC3 may be arranged in a zigzag shape to establish or achieve a certain or predetermined distance between consecutive or nearest word line contacts.

The word line contacts WLC1, WLC2, and WLC3 extend in the third direction Z and are connected to the peripheral circuit structure 45 shown in FIG. 2A and FIG. 2B. For example, each of the word line contacts WLC1, WLC2, and WLC3 is connected to a different one of the pass transistors PT shown in FIG. 3.

The ends of the first and second extending members VP1 and VP2 of each of the gate conductive patterns GCP1, GCP2, and GCP3 extend in the second direction Y within the word line contact region. The gate conductive patterns GCP1, GCP2, and GCP3 may have a symmetrical structure such that the gate conductive patterns GCP1, GCP2, and GCP3 have mirror image in the first direction X with respect to the center of the word line contact region. For example, a structure of the gate conductive patterns GCP1, GCP2, and GCP3 disposed to extend from the first cell region to the word line contact region and a structure of the first to third gate conductive patterns GCP1, GCP2, and GCP3 disposed to extend from the word line contact region to the second cell region may be symmetrical.

As described, in accordance with an embodiment of the present disclosure, the gate conductive patterns GCP1, GCP2, and GCP3 are formed within the first cell region and the second cell region. Accordingly, a memory block formed in the first cell region and a memory block formed in the second cell region may share word lines. Each of the gate conductive patterns GCP1, GCP2, and GCP3 are connected to the word line contacts WLC1, WLC2, and WLC3 in the word line contact region between the first cell region and the second cell region. Word line operating voltages may be transmitted or transferred to each of the first cell region and the second cell region through the word line contacts WLC1, WLC2, and WLC3.

In the embodiment of FIG. 4, the word line contacts WCL1, WCL2, and WLC3 connected to each of the first to third gate conductive patterns GCP1, GCP2, and GCP3 are disposed in a section of the word line contact region, which section is adjacent to the first cell region. The word line contacts connected to each of the gate conductive patterns GCP1, GCP2, and GCP3 are disposed in a section of the word line contact region, which section is adjacent to the second cell region.

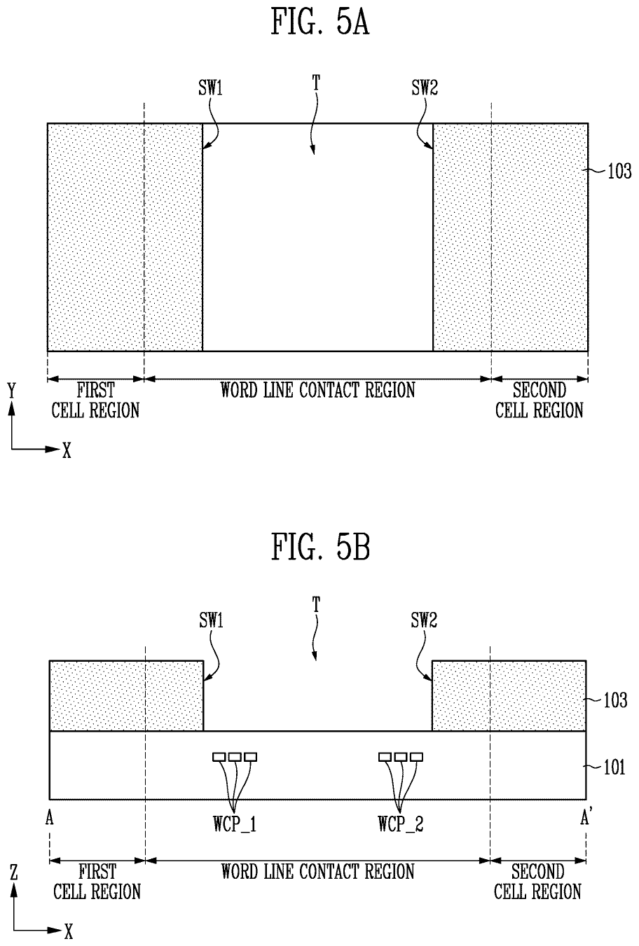

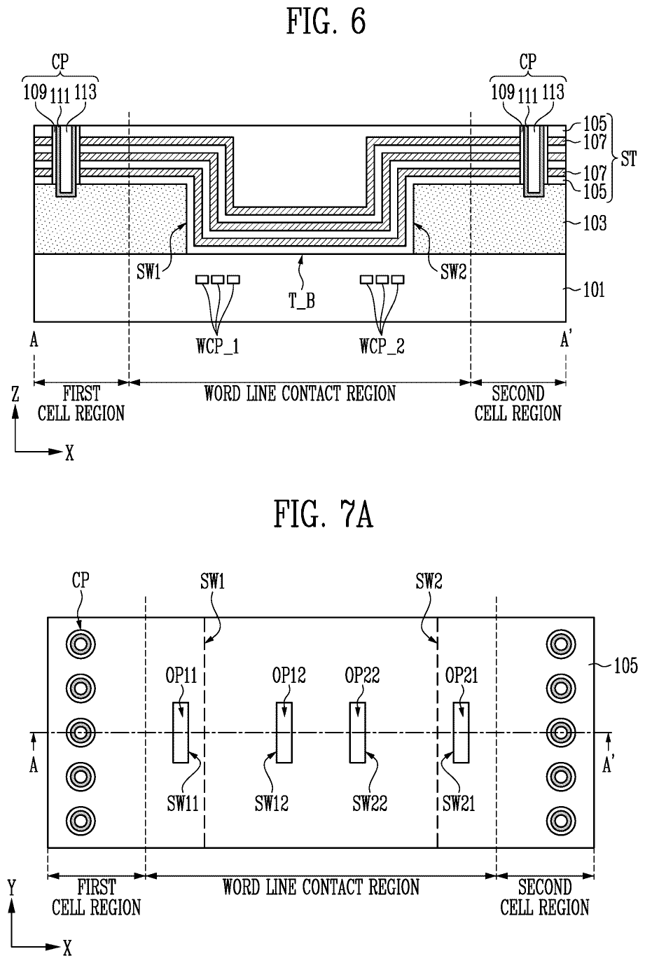

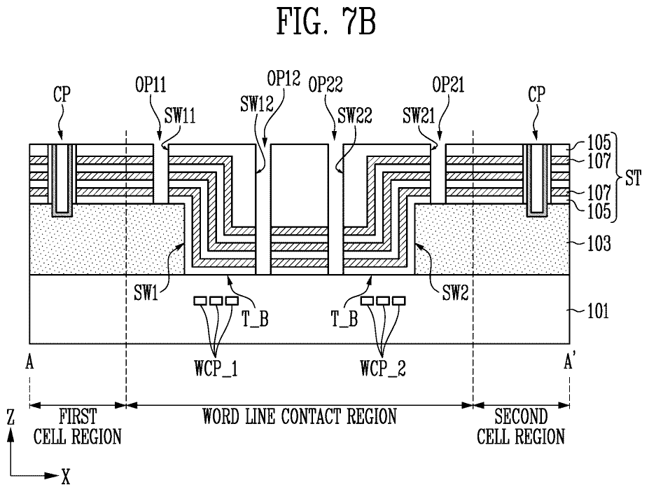

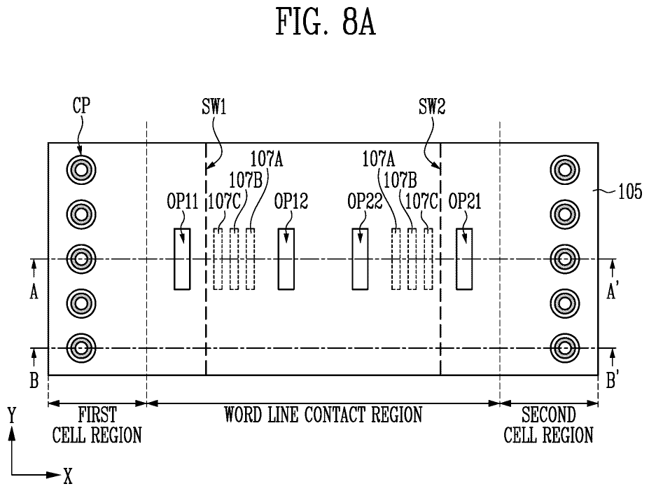

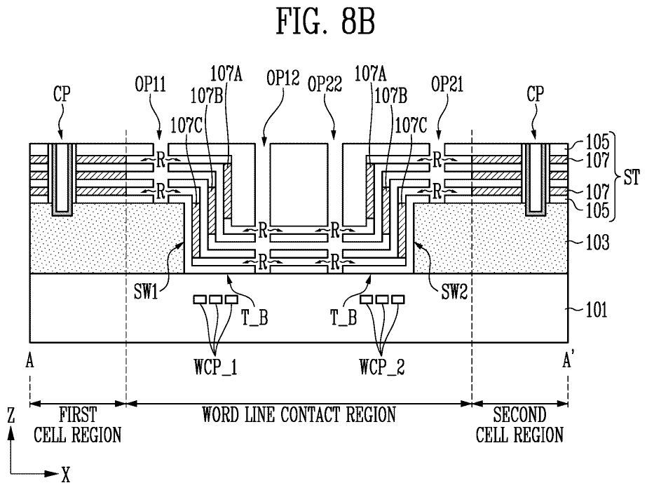

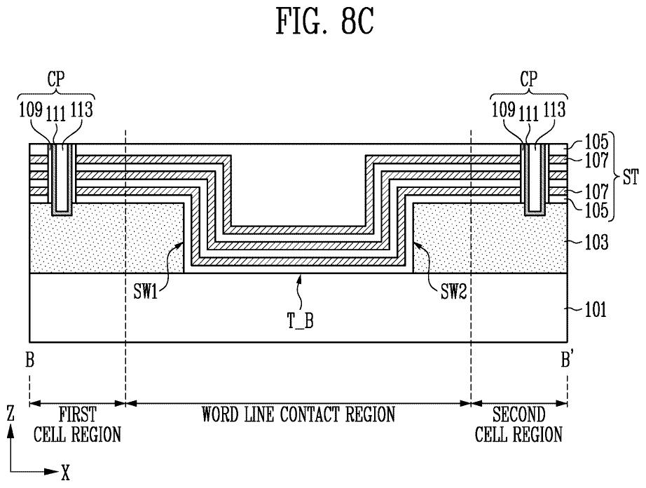

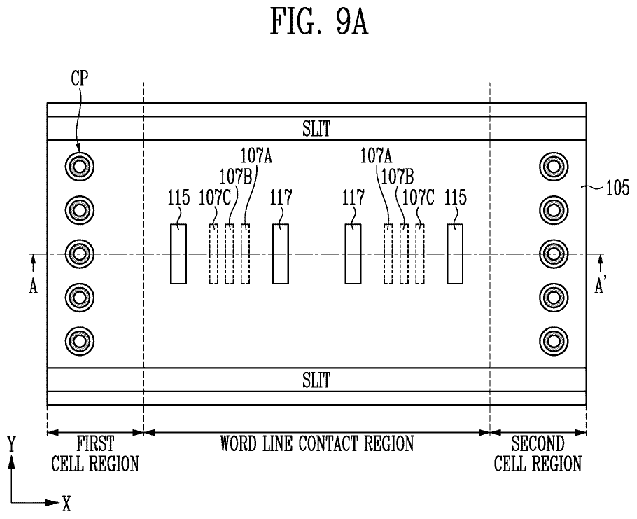

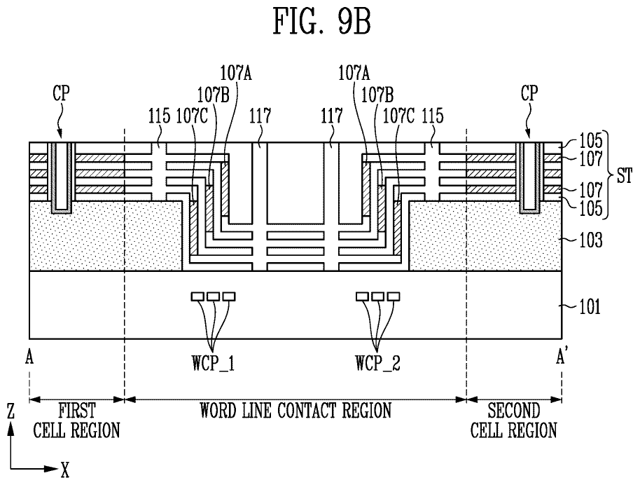

FIG. 5A, FIG. 5B, FIG. 6, FIG. 7A, FIG. 7B, FIG. 8A, FIG. 8B, FIG. 8C, FIG. 9A, FIG. 9B, FIG. 10, FIG. 11A, and FIG. 11B are views of a memory device formed utilizing a method of manufacturing the memory device in accordance with an embodiment of the present disclosure.

Referring to FIG. 5A and FIG. 5B, first word line contact pads WCP_1 and second word line contact pads WCP_2, which are electrically connected to a peripheral circuit, are formed on a substrate on which the peripheral circuit is formed. The first word line contact pads WCP_1 and the second word line contact pads WCP_2 are electrically connected to the pass transistors PT included in the block select circuit BSC of the row decoder 33 described with reference to FIG. 1 and FIG. 3. The peripheral circuit may be similar to the peripheral circuit 40 described with reference to FIG. 1. The substrate includes a first cell region, a word line contact region, and a second cell region. The first word line contact pads WCP_1 and the second word line contact pads WCP_2 are formed within the word line contact region.

An insulating structure 101 is formed to cover the first word line contact pads WCP_1 and the second word line contact pads WCP_2.

A doped semiconductor layer 103 is formed on the insulating structure 101. The doped semiconductor layer 103 is formed to include at least one of an n-type dopant and a p-type dopant. In an embodiment, the doped semiconductor layer 103 includes an n-type doped silicon layer.

A trench T through which the insulating structure 101 is exposed is formed by etching the doped semiconductor layer 103 formed within the word line contact region. The trench T extends in the first direction X and the second direction Y. During a process including forming the trench T, the doped semiconductor layer 103 is etched resulting in a first sidewall SW1 and a second sidewall SW2. The first sidewall SW1 and the second sidewall SW2 extend in parallel to each other in the second direction Y and in the third direction Z. The first sidewall SW1 is formed nearest to the first cell region, and the second sidewall SW2 is formed nearest to the second cell region. The trench T is formed over the first word line contact pads WCP_1 and the second word line contact pads WCP_2.

The doped semiconductor layer 103 may be a source layer used as the common source line CSL such as shown in FIG. 3.

Referring to FIG. 6, a stack structure ST is formed by alternately stacking interlayer insulating layers 105 with sacrificial layers 107 on the top of or over the structure including the doped semiconductor layer 103 and the insulating structure 101 of FIG. 5B. The stack structure ST is formed on an upper surface of the doped semiconductor layer 103, the first sidewall SW1, an upper surface of the insulating structure 101 adjacent to the bottom T-B of the trench, and the second sidewall SW2. The sacrificial layers 107 formed along the first sidewall SW1 and the second sidewall SW2 extend in the third direction Z. An uppermost interlayer insulating layer 105 among the interlayer insulating layers 105 is formed with a thickness such that the trench T shown in FIG. 5A is completely filled, and the top of the stack structure ST, the uppermost interlayer insulating layer 105, is formed to have a uniform height in the first cell region, the word line contact region, and the second cell region.

The sacrificial layers 107 include a material having an etch selectivity with respect to the interlayer insulating layers 105. The interlayer insulating layers 105 are formed including an insulating material capable of insulating between gate conductive patterns subsequently formed. In an embodiment, the interlayer insulating layers 105 may include an oxide layer such as silicon oxide, and the sacrificial layers 107 may include a nitride layer such as silicon nitride.

The interlayer insulating layers 105 and the sacrificial layers 107 within the first cell region and the second cell region are etched, thereby forming channel holes penetrating the interlayer insulating layers 105 and the sacrificial layers 107 and forming cell plugs CP in the channel holes. The cell plugs CP extend into the doped semiconductor layer 103.

For example, the channel holes are formed, which extend into the doped semiconductor layer 103 through the interlayer insulating layers 105 and the sacrificial layers 107, and a memory layer 109 is formed along sidewalls of the insulating layers 105 and the sacrificial layers 107 adjacent to the channel holes. The memory layer 109 includes a blocking insulating layer, a charge storage layer, and a tunnel insulating layer. An etching process including removing the memory layer 109 formed on bottom surfaces of the channel holes is performed. A channel layer 111 is formed along the memory layer 109 and the bottom surfaces of the channel holes, and the cell plugs CP are formed by filling the channel layer with a core insulating layer 113. The channel layer 111 extends inside the doped semiconductor layer 103 and is in direct contact with the doped semiconductor layer 103. The channel layer 111 includes a semiconductor layer used as a channel region of a memory string.

Referring to FIG. 7A and FIG. 7B, the stack structure ST within the word line contact region is etched, thereby forming a first opening OP11, a second opening OP12, a first opening OP21, and a second opening OP22. The first opening is located between the first sidewall SW1 and the first cell region, and the doped semiconductor layer 103 is exposed through the first opening OP11. The first opening OP21 is located between the second sidewall SW2 and the first cell region, and the doped semiconductor layer 103 is exposed through the first opening OP21. The second opening OP12 is disposed within the U channel formed in the middle of the word line contact region and formed nearest to the first sidewall SW1, and the insulating structure 101 is exposed through the second opening OP12. The second opening OP22 is disposed within the U channel formed in the middle of the word line contact region and formed nearest to the second sidewall SW2 and the insulating structure 101 is exposed through the second opening OP22.

The first opening OP11 has a sidewall SW11 parallel to the first sidewall SW1, and the second opening OP12 has a sidewall SW12 nearest to the first sidewall SW1. For example, the first opening OP11 and the second opening OP12 may be formed having a quadrangular or box shape.

The first opening OP21 has a sidewall SW21 parallel to the second sidewall SW2, and the second opening OP22 has a sidewall SW22 parallel to the second sidewall SW2. For example, the first opening OP21 and the second opening OP22 may be formed in a quadrangular or box shape.

The first openings OP11 and OP21 are disposed outside the trench T shown in FIG. 5B within the word line contact region, and the second openings OP12 and OP22 are disposed inside the trench T shown in FIG. 5B within the word line contact region.

A distance between the sidewalls SW11 and SW21 of the first openings OP11 and OP21 and a part extending in the third direction Z of a lowermost sacrificial layer among the sacrificial layers 107 is equal to or substantially equal to a distance between the sidewalls SW12 and SW22 of the second openings OP12 and OP22 and a part extending in the third direction Z of an uppermost sacrificial layer among the sacrificial layers 107.

Referring to FIG. 8A, FIG. 8B, and FIG. 8C, the sacrificial layers 107 exposed through the first openings OP11 and OP21 and the second openings OP12 and OP22 are partially etched, thereby forming recess regions R. During an etching process that forms the recess regions R, an etch rate may be adjusted such that sacrificial layers 107A, 107B, and 107C extending in the third direction Z and parallel to the first sidewall SW1 and the second sidewall SW2 remain as shown in region B-B′ of FIG. 8B. The remaining sacrificial layers are described as first to third sacrificial patterns 107A, 107B, and 107C, and the first to third sacrificial patterns 107A, 107B, and 107C are formed in a region adjacent to each of the first sidewall SW1 and the second sidewall SW2. The first to third sacrificial patterns 107A, 107B, and 107C may be disposed at different heights or levels in the third direction Z, where the lower ends of the sacrificial patterns 107A, 107B, and 107C are at different levels in the third direction Z, and the upper ends of the sacrificial patterns 107A, 107B, and 107C are at different levels in the third direction Z.

During the etching process, in a region, for example, region B-B′ shown in FIG. 8A, which is spaced apart from the first openings OP11 and OP21 and the second openings OP12 and OP22, the sacrificial layers 107 are not removed but and remain within the first cell region, the word line contact region, and the second cell region as shown in FIG. 8C.

Referring to FIG. 9A and FIG. 9B, an upper insulating pattern 115 is formed by filling the first openings OP11 and OP21 shown in FIG. 8B and the recess region R shown in FIG. 8B with an insulating material. A lower insulating pattern 117 is formed by filling the second openings OP12 and OP22 shown in FIG. 8B and the recess regions R shown in FIG. 8B) with an insulating material.

A slit SLIT is formed that extends through the stack structure ST in the first direction X. The slit SLIT is formed to be disposed outside or beyond the region where the cell plugs CP are disposed.

Referring to FIG. 10, the sacrificial layers 107 shown in FIG. 9B and the first to third sacrificial patterns 107A, 107B, and 107C shown in FIG. 9B, which are exposed through the slit SLIT shown in FIG. 9A are removed. Gate conductive patterns 119 are formed by filling a conductive material in spaces where the sacrificial layers and the sacrificial patterns 107A, 107B, and 107C are removed. The gate conductive patterns formed in the spaces where the sacrificial patterns 107A, 107B, and 107C are removed are referred to as connection patterns 119A, 119B, and 119C. An upper surface of each of the first to third connection patterns 119A, 119B, and 119C contacts the upper insulating pattern 115, and a lower surface of each of the first to third connection patterns 119A, 119B, and 119C contacts the lower insulating pattern 117. A gate stack structure GST includes the gate conductive patterns 119 alternately stacked with the interlayer insulating layers 105.

Referring to FIG. 11A and FIG. 11B, the slit SLIT is filled with an insulating material. First to third word line contacts WLC_A, WLC_B, and WLC_C are formed through the gate stack structure GST in the word line contact region. The word line contacts WLC_A, WLC_B, and WLC_C are formed at least partially in contact with the first to third connection patterns 119A, 119B, and 119C, respectively.

The first word line contact WLC_A extends through the interlayer insulating layers 105, the upper insulating pattern 115, the first connection pattern 119A, and the lower insulating pattern 117 and extends inside the insulating structure 101, where each of the first word line contacts WLC_A is connected to one of the first word line contact pads WCP_1 or one of the second word line contact pads WCP_2.

The second word line contact WLC_B extends through the interlayer insulating layers 105, the upper insulating pattern 115, the second connection pattern 119B, and the lower insulating pattern 117 and extends inside the insulating structure 101, where each of the second word line contacts WLC_B is connected to one of the first word line contact pads WCP_1 or one of the second word line contact pads WCP_2.

The third word line contact WLC_C extends through the interlayer insulating layers 105, the upper insulating pattern 115, the third connection pattern 119C, and the lower insulating pattern 117 and extends inside the insulating structure 101, where each of the third word line contacts WLC_C is connected to one of the first word line contact pads WCP_1 or one of the second word line contact pads WCP_2.

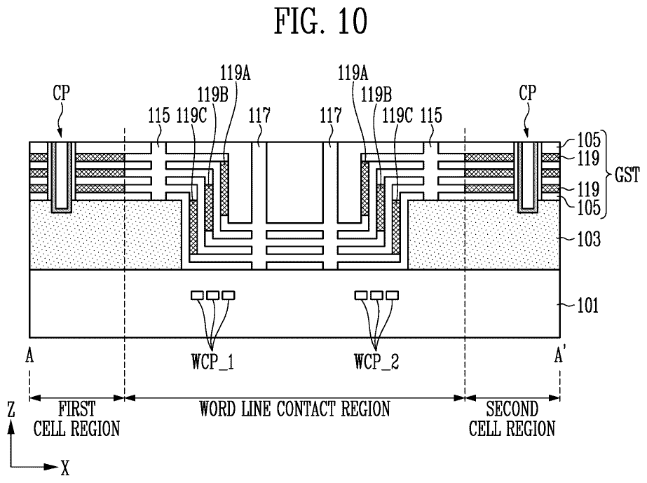

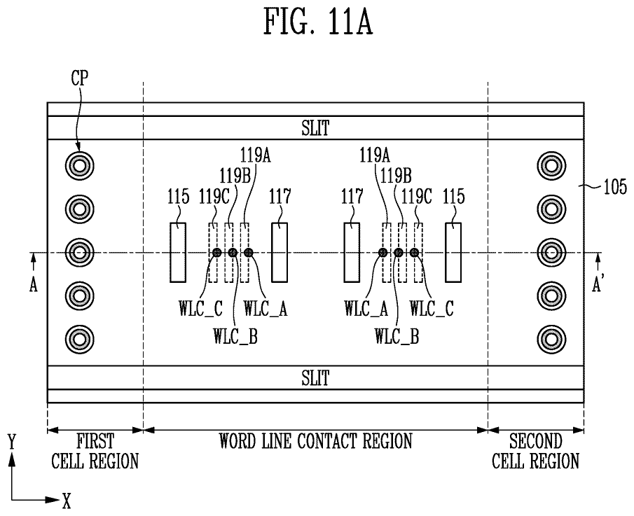

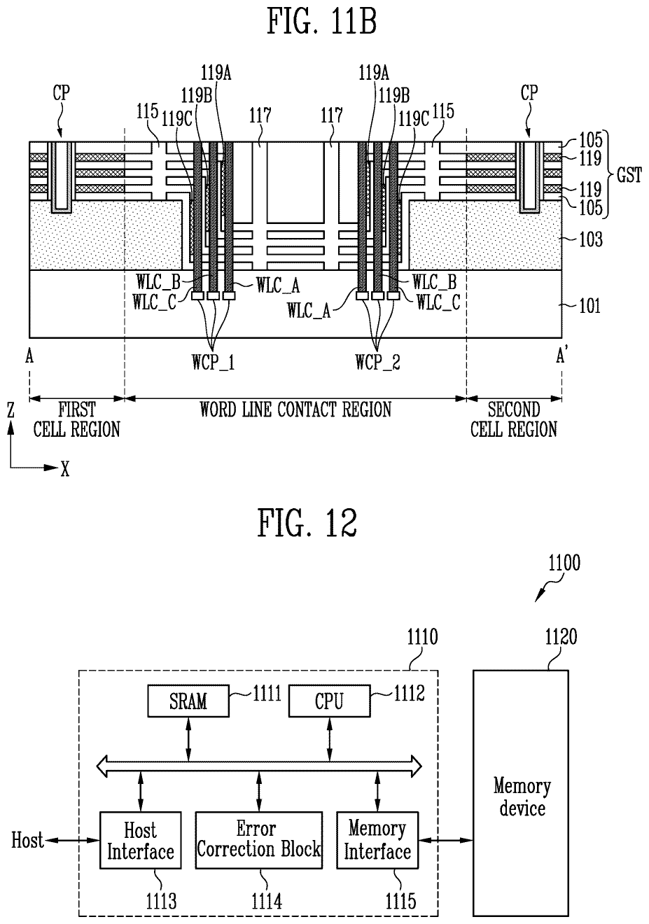

FIG. 12 is a block diagram illustrating a configuration of a memory system in accordance with an embodiment of the present disclosure.

Referring to FIG. 12, the memory system 1100 includes a memory device 1120 and a memory controller 1110.

The memory device 1120 is a multi-chip package configured with a plurality of flash memory chips. The memory device 1120 includes a peripheral circuit structure formed on a substrate and a stack structure formed on the peripheral circuit structure. The stack structure includes a cell stack structure. The cell stack structure includes a connection structure including gate conductive patterns and word line contacts, for example, as shown in FIG. 4 and the other figures. The word line contacts extend through the cell stack structure into the peripheral circuit structure and connect to word line contact pads disposed in the peripheral circuit structure.

The memory controller 1110 controls the memory device 1120 and includes a Static Random Access Memory (SRAM) 1111, a Central Processing Unit (CPU) 1112, a host interface 1113, an error correction block 1114, and a memory interface 1115. The SRAM 1111 is used as operation memory for the CPU 1112, the CPU 1112 performs overall control operations for data exchange by the memory controller 1110, and the host interface 1113 includes a data exchange protocol for a host connected with the memory system 1100. The error correction block 1114 detects errors included in data read from the memory device 1120 and corrects the detected errors. The memory interface 1115 interfaces with the memory device 1120. The memory controller 1110 may further include a Read Only Memory (ROM) that stores code data for interfacing with the host and the like.

The memory system 1100 may be a memory card or a Solid State Disk (SSD), in which the memory device 1120 is combined with the controller 1110. For example, when the memory system 1100 is an SSD, the memory controller 1100 may communicate with a device outside the memory controller 1110 and/or memory device 1120, for example, a host, through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer Small Interface (SCSI) protocol, an Enhanced Small Disk Interface (ESDI) protocol, and an Integrated Drive Electronics (IDE) protocol.

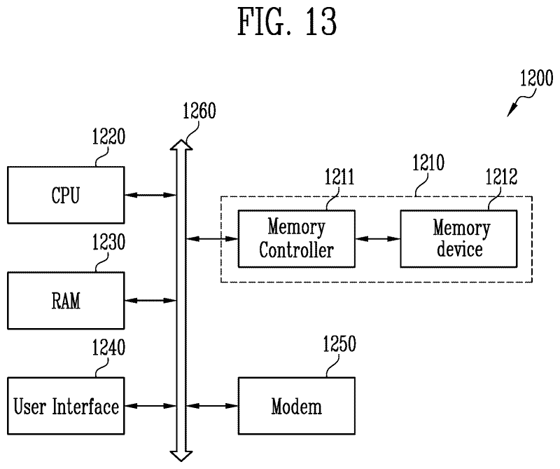

FIG. 13 is a block diagram illustrating a configuration of a computing system in accordance with an embodiment of the present disclosure.

Referring to FIG. 13, the computing system 1200 includes a CPU 1220, a random access memory (RAM) 1230, a user interface 1240, a modem 1250, and a memory system 1210, which are electrically connected to a system bus 1260. When the computing system 1200 is a mobile device, a battery that supplies an operation voltage to the computing system 1200 is included, and an application chip set, an image processor, a mobile D-RAM, and the like may be included.

The memory system 1210 is configured with a memory device 1212 and a memory controller 1211. The memory device 1212 is configured similarly to the memory device 1120 described with reference to FIG. 12. The memory controller 1211 is configured similarly to the memory controller 1110 described with reference to FIG. 12.

In accordance with the present disclosure, word line contacts connected to word lines corresponding to each of memory blocks are formed in a region between the memory blocks, and a word line voltage may be transmitted to each of neighboring memory blocks through the word line contacts, thereby improving the degree of integration.

In the embodiments, the processes of the method may be selectively performed or a subset of the processes and may be performed. In each embodiment, the processes are not necessarily performed in accordance with the order as described and may be rearranged. The embodiments disclosed in this specification and drawings are examples provided to facilitate an understanding of the present disclosure, and the present disclosure is not limited to these examples or embodiments.

In accordance with an embodiment of the present disclosure, a memory device may include a first gate conductive pattern comprising a first extension extending in a first direction and a first extending member extending in a third direction from an end of the first extension, a second extension extending in the first direction and a second extending member extending in the third direction from an end of the second extension, and a first connection between the first extending member and the second extending member; and a second gate conductive pattern comprising a third extension extending in the first direction and a third extending member extending in the third direction from an end of the third extension, a fourth extension extending in the first direction and a fourth extending member extending in the third direction from an end of the fourth extension, and a second connection between the third extending member and the fourth extending member. The memory device of may further comprise a first insulating pattern located between the first extension and the second extension and at a first end of the first connection; a second insulating pattern located at a second end of the first connection; a third insulating pattern located between the third extension and the fourth extension and at a first end of the second connection; a fourth insulating pattern located at a second end of the second connection; a first word line contact extending in the third direction through the first connection, the first insulating pattern, the first extending member, the second extending member, the second insulating pattern, and the fourth insulating pattern; and a second word line contact extending in the third direction through the second connection, the first insulating pattern, the third insulating pattern, the first extending member, the second extending member, and the fourth insulating pattern.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

What is claimed is:

1. A memory device comprising:
a first gate conductive pattern disposed within a cell region and a word line contact region and extending in a first direction; and
a second gate conductive pattern sequentially disposed with the first gate conductive pattern and extending in the first direction,
wherein each of the first gate conductive pattern and the second gate conductive pattern includes:
a first extension extending in parallel with a second extension in the first direction within the word line contact region;
a first extending member extending in a third direction from an end of the first extension and a second extending member extending in the third direction from an end of the second extension, wherein the third direction is orthogonal to the first direction; and
a connection connecting the first extending member to the second extending member.

2. The memory device of claim 1, wherein the first extending member of the first gate conductive pattern and the first extending member of the second gate conductive pattern are sequentially arranged in the first direction, and the second extending member of the first gate conductive pattern and second extending member of the second gate conductive pattern are sequentially arranged in the first direction.

3. The memory device of claim 1, wherein a first end of the connection of the first gate conductive pattern and a first end of the connection of the second gate conductive pattern are located at different levels in the third direction.

4. The memory device of claim 1, further comprising:
a first word line contact extending in the third direction through the connection of the first gate conductive pattern; and
a second word line contact extending in the third direction through the connection of the second gate conductive pattern.

5. The memory device of claim 1, further comprising:
a first insulating pattern located between the first extension and the second extension of the first gate conductive pattern and between a first end of the first extending member and a first end of the second extending member of the first gate conductive pattern; and
a second insulating pattern located between a second end of the first extending member and a second end of the second extending member of the first gate conductive pattern;
wherein the connection of the first gate conductive pattern is disposed between the first insulating pattern and the second insulating pattern.

6. The memory device of claim 5, further comprising:
a third insulating pattern located between the first extension and the second extension of the second gate conductive pattern and between a first end of the first extending member and a first end of the second extending member of the second gate conductive pattern; and
a fourth insulating pattern located between a second end of the first extending member and a second end of the second extending member of the second gate conductive pattern,
wherein the connection of the second gate conductive pattern is disposed between the third insulating pattern and the fourth insulating pattern.

7. The memory device of claim 6, wherein the first word line contact extends in the third direction through the first insulating pattern, the first extending member and the second extending member of the first gate conductive pattern, the second insulating pattern, and the fourth insulating pattern.

8. The memory device of claim 7, wherein the second word line contact extends in the third direction through the first insulating pattern, the third insulating pattern, the first extending member and the second extending member of the second gate conductive pattern, and the fourth insulating pattern.

9. The memory device of claim 4, wherein the first word line contact and the second word line contact:
are arranged in a straight line in the first direction, or
are arranged in an oblique direction between the first direction and a second direction orthogonal to the first direction.

10. A memory device comprising:
a first gate conductive pattern disposed within a first cell region, a word line contact region, and a second cell region, which first cell region, word line contact region, and second cell region are sequentially disposed and extend in a first direction; and
a second gate conductive pattern sequentially disposed with the first gate conductive pattern and extending in the first direction,
wherein each of the first gate conductive pattern and the second gate conductive pattern includes:
a first extension extending in parallel with a second extension in the first direction within the word line contact region;
a first extending member extending in a third direction from an end of the first extension and a second extending member extending in the third direction from an end of the second extension, wherein the third direction is orthogonal to the first direction; and
a connection connecting the first extending member to the second extending member, and
wherein the first gate conductive pattern and the second gate conductive pattern have a concave pattern shape within the word line contact region.

11. The memory device of claim 10, further comprising a doped semiconductor layer formed within the first cell region and the second cell region,
wherein the doped semiconductor layer has a first sidewall and a second sidewall extending in the third direction within the word line contact region.

12. The memory device of claim 11, wherein the first gate conductive pattern and the second gate conductive pattern are disposed on the doped semiconductor layer, the first sidewall, and the second sidewall.

13. The memory device of claim 11, wherein the first extending member of the first gate conductive pattern and the first extending member of the second gate conductive pattern are sequentially arranged in the first direction, and the second extending member of the first gate conductive pattern and second extending member of the second gate conductive pattern are sequentially arranged in the first direction.

14. The memory device of claim 10, wherein a first end of the connection of the first gate conductive pattern and a first end of the connection of the second gate conductive pattern are located at different levels in the third direction.

15. The memory device of claim 10, further comprising:
a first word line contact extending in the third direction through the connection of the first gate conductive pattern; and
a second word line contact extending in the third direction through the connection of the second gate conductive pattern.

16. The memory device of claim 10, further comprising:
a first insulating pattern located between the first extension and the second extension of the first gate conductive pattern and between a first end of the first extending member and a first end of the second extending member of the first gate conductive pattern; and
a second insulating pattern located between a second end of the first extending member and a second end of the second extending member of the first gate conductive pattern,
wherein the connection of the first gate conductive pattern is disposed between the first insulating pattern and the second insulating pattern.

17. The memory device of claim 16, further comprising:
a third insulating pattern located between the first extension and the second extension of the second gate conductive pattern and between a first end of the first extending member and a first end of the second extending member of the second gate conductive pattern; and
a fourth insulating pattern located between a second end of the first extending member and a second end of the second extending member of the second gate conductive pattern,
wherein the connection of the second gate conductive pattern is disposed between the third insulating pattern and the fourth insulating pattern.

18. The memory device of claim 17, wherein the first word line contact extends in the third direction through the first insulating pattern, the first extending member and the second extending member of the first gate conductive pattern, the second insulating pattern, and the fourth insulating pattern.

19. The memory device of claim 18, wherein the second word line contact extends in the third direction through the first insulating pattern, the third insulating pattern, the first extending member and the second extending member of the second gate conductive pattern, and the fourth insulating pattern.

20. A method of manufacturing a memory device, the method comprising:
forming an insulating structure, including word line contact pads, on a substrate including a first cell region, a word line contact region, and a second cell region;
forming a doped semiconductor layer on the insulating structure and etching the doped semiconductor layer formed within the word line contact region to form a trench between a first sidewall and a second sidewall of the doped semiconductor layer;
forming a stack structure in which interlayer insulating layers are alternately stacked with sacrificial layers on the doped semiconductor layer, the first sidewall, the second sidewall, and a surface of the insulating structure adjacent to the trench;
forming in the stack structure a first opening near the first sidewall through which a surface of the doped semiconductor layer is exposed and a second opening near the first sidewall through which a surface of the insulating structure adjacent to the trench is exposed by etching the stack structure within the word line contact region;
forming sacrificial patterns extending in a third direction parallel to the first sidewall by partially etching the sacrificial layers exposed through the first opening and the second opening; and
forming insulating patterns by filling, with an insulating material, the first opening, the second opening, and spaces where the sacrificial layers are removed by the etching.

21. The method of claim 20, further comprising:
forming a slit extending in a first direction by etching the stack structure; and
removing the sacrificial layers and the sacrificial patterns exposed through the slit and forming gate conductive patterns by filling spaces where the sacrificial layers are removed with a conductive material, and forming extending members by filling spaces in which the sacrificial patterns are removed with the conductive material.

22. The method of claim 21, further comprising forming a plurality of word line contacts extending in the third direction through the insulating pattern and the extending members.

23. The method of claim 20, wherein a first sidewall of the stack structure adjacent to the first opening and a second sidewall of the stack structure adjacent to the second opening are formed parallel to the first sidewall.

24. The method of claim 20, wherein each of the first opening and the second opening is formed having a quadrangular shape.

25. The method of claim 20, wherein ends of the sacrificial patterns are formed to be located at different levels in the third direction.
